(19) United States
(12) Patent Application Publication
(10) Pub. No.: US 2012/0145224 A1
(43) Pub. Date: Jun. 14, 2012

(54) SOLAR CELL MODULE AND METHOD FOR MANUFACTURING SAME

(75) Inventors: Wataru Shinohara, Ogaki-shi (JP); Satoru Ogasahara, Aichi (JP)

(73) Assignee: Sanyo Electric Co., Ltd., Moriguchi-shi (JP)

(21) Appl. No.: 13/389,573

(22) PCT Filed: Aug. 17, 2010
(86) PCT No.: PCT/JP2010/063843

§ 371 Date: Feb. 8, 2012

(30) Foreign Application Priority Data
Aug. 19, 2009 (JP) 2009-190249
Aug. 20, 2009 (JP) 2009-190688
Jul. 29, 2010 (JP) 2010-170554

(51) Int. Cl. H01L 31/05; H01L 31/0224

(52) U.S. Cl. 136/249; 438/80; 257/E31.124

(57) ABSTRACT

Disclosed is a solar cell module wherein peeling between a substrate and a photoelectric conversion layer is not easily generated. In the solar cell module, a plurality of photoelectric conversion elements, each of which has a transparent electrode (12), a photoelectric conversion unit (14), and a rear surface electrode (16) sequentially stacked on a transparent substrate (10), are connected in series, and the solar cell module is provided with a slit (S2) formed by removing the transparent electrode (12) to a first width (D1), and a slit (S5), which overlaps the region where the transparent electrode (12) has been removed, and which has the photoelectric conversion unit (14) and the rear surface electrode (16) removed therefrom to a second width (D2) that is equal to or less than the first width (D1). On the surface of the transparent substrate (10) in the slit (S2), recesses and protrusions (34) are provided.

### BACKGROUND OF THE INVENTION

1. Field of the Invention

The present invention relates to a solar cell module and a manufacturing method thereof.

2. Description of the Related Art

Solar cell modules using polycrystalline, microcrystalline, and amorphous silicones are known. In particular, a solar cell module having a stacked structure of thin films made of microcrystalline or amorphous silicone has been attracting increasing attention in view of consumption of resources, cost reduction, and improved efficiency.

FIG. 8 is a schematic sectional view showing a basic structure of a solar cell module 100. The solar cell module 100 typically includes a structure consisting of a transparent electrode 12, a photoelectric conversion unit 14 and a rear surface electrode 16 sequentially stacked on a transparent substrate 10 made of glass or the like, and the solar cell module 100 generates power by emitting light through the transparent substrate 10. Methods and patterning devices for integrating such solar cell modules in series have been disclosed (e.g., Patent Document 1).

FIGS. 9(a)-9(f) show a manufacturing process of a conventional solar cell module 100. In FIGS. 9(a)-9(f), each step of the manufacturing process of the solar cell module 100 is shown schematically by a plan view and a sectional view. Sectional views show sections cut along lines A-A and B-B, respectively, of the plan views.

In step S10, as shown in FIG. 9(a), a slit S1 is formed by laser processing to divide a transparent electrode 12 disposed on a transparent substrate 10 made of glass or the like, and a slit S2 is also formed in a direction perpendicular to the slit S1. In step S12, as shown in FIG. 9(b), a photoelectric conversion unit 14 which serves as a photoelectric conversion layer is disposed to cover the transparent electrode 12. The photoelectric unit 14 may be an amorphous silicon (a-Si) photoelectric conversion unit, a microcrystalline silicone (μc-Si) photoelectric conversion unit, or a tandem structure of such units. In step S14, as shown in FIG. 9(c), a slit S3 is formed by laser processing to divide the photoelectric conversion unit 14 in the direction of the slit S1 at a position in the vicinity of and not overlapping the slit S1. In step S16, as shown in FIG. 9(d), a rear surface electrode 16 is formed to cover the photoelectric conversion unit 14. In step S18, as shown in FIG. 9(e), a slit S4 is formed by laser processing to divide the photoelectric conversion unit 14 and the rear surface electrode 16 in the direction of slits S1 and S3 at a position in the vicinity of the slit S3 and not overlapping the slits S1 and S3. Accordingly, the structure of multiple solar cells connected in series in the direction of the slit S2 is provided. In step S20, as shown in FIG. 9(f), a slit S5 is formed by laser processing to divide the photoelectric conversion unit 14 and the rear surface electrode 16 disposed in the slit S2. As a result, the solar cells arranged adjacent to each other in the direction of the slit S1 are electrically separated from each other, thereby providing a structure of a group of solar cells consisting of serially connected multiple solar cells. Then, these solar cells are finally connected in parallel to provide a solar cell module 100.

Patent Document 1: JP No. 2001-320071A.

The conventional solar cell module has a structure in which the photoelectric conversion unit 14 serving as the photoelectric conversion layer is in direct contact with the surface of the transparent substrate 10 formed by a glass substrate or the like in the slit S2 which divides the serially connected solar cells into a plurality of solar cell groups. This type of structure has a problem that peeling occurs easily between the transparent substrate 10 and the photoelectric conversion layer.

An object of the present invention is to provide a solar cell module and a manufacturing method thereof, in which the likelihood of peeling between the substrate and the photoelectric conversion layer is diminished and durability is improved.

### SUMMARY OF THE INVENTION

According to an embodiment of the present invention, a solar cell module consists of a plurality of photoelectric conversion elements connected in series, each of which has a first electrode, an electricity generating layer, and a second electrode sequentially stacked on a substrate, wherein the solar cell module includes a dividing slit having a region where the first electrode is removed to a first width, and a region which overlaps the region where the first electrode has been removed, and the electricity generating layer and the second electrode removed therefrom with a second width narrower than the first width, and recesses and protrusions are provided on the surface of the substrate in the dividing slit.

According to another embodiment of the present invention, a method of manufacturing a solar cell module consisting of a plurality of photoelectric conversion elements connected in series, each of which having a first electrode, an electricity generating layer, and a second electrode sequentially stacked on a substrate, includes: a first step of forming the first electrode on the substrate; a second step of removing a part of the first electrode to a first width and forming recesses and protrusions on the surface of the substrate by blasting a region where the first electrode is removed; a third step including sequentially stacking the electricity generating layer and the second electrode on the substrate; and a fourth step of removing the electricity generating layer and the second electrode with a second width narrower than the first width in a region which overlaps the region where the first electrode is removed.

According to another embodiment of the present invention, a solar cell module consists of a plurality of photoelectric conversion elements connected in series, each of which having a first electrode, an electricity generating layer, and a second electrode sequentially stacked on a substrate, wherein the solar cell module includes a first slit having an island arranged in the direction of the serial connection of the photoelectric conversion elements and sandwiched by a plurality of slits from which the first electrode is removed to leave the island of the first electrode, and a second slit formed within the region where the first slit is provided, and having the first electrode, the electricity generating layer, and the second electrode removed therefrom to reach the substrate.

According to still another embodiment of the present invention, a method of manufacturing a solar cell module consisting of a plurality of photoelectric conversion elements connected in series, each of which having a first electrode, an electric generating layer, and a second electrode sequentially stacked on a substrate includes: a first step of forming the first electrode on the substrate; a second step of forming a first slit having an island arranged in the direction of the serial connection of the photoelectric conversion elements and sandwiched by a plurality of slits from which the first electrode is removed to leave the island of the first electrode; a third step of sequentially stacking the electricity generating layer and the second electrode on the first electrode including at least part of the island; and a fourth step of forming a second slit by removing the first electrode, the electric generating layer, and the second electrode in the region where the first slit is formed, so that the second slit reaches the substrate.

The present invention advantageously provides a solar cell module which reduces the likelihood of peeling between the substrate and the photoelectric conversion layer, while improving the durability and stability.

### BRIEF DESCRIPTION OF THE DRAWINGS

FIG. 1(a) is a plan view and sectional views showing a manufacturing process of a solar cell module according to a first embodiment of the present invention;

FIG. 1(b) is a plan view and sectional views showing a manufacturing process of a solar cell module according to a first embodiment of the present invention;

FIG. 1(c) is a plan view and sectional views showing a manufacturing process of a solar cell module according to a first embodiment of the present invention;

FIG. 1(d) is a plan view and sectional views showing a manufacturing process of a solar cell module according to a first embodiment of the present invention;

FIG. 1(e) is a plan view and sectional views showing a manufacturing process of a solar cell module according to a first embodiment of the present invention;

FIG. 1(f) is a plan view and sectional views showing a manufacturing process of a solar cell module according to a first embodiment of the present invention.

FIG. 2 is a sectional view of a manufacturing process of a solar cell module according to a first embodiment of the present invention;

FIG. 3 is a sectional view of a solar cell module according to a first embodiment of the present invention;

FIG. 4(a) is a plan view and sectional views of a manufacturing process of a solar cell module according to a second embodiment of the present invention;

FIG. 4(b) is a plan view and sectional views of a manufacturing process of a solar cell module according to a second embodiment of the present invention;

FIG. 4(c) is a plan view and sectional views of a manufacturing process of a solar cell module according to a second embodiment of the present invention;

FIG. 4(d) is a plan view and sectional views of a manufacturing process of a solar cell module according to a second embodiment of the present invention;

FIG. 4(e) is a plan view and sectional views of a manufacturing process of a solar cell module according to a second embodiment of the present invention;

FIG. 4(f) is a plan view and sectional views of a manufacturing process of a solar cell module according to a second embodiment of the present invention;

FIG. 4(g) is a plan view and sectional views of a manufacturing process of a solar cell module according to a second embodiment of the present invention.

FIG. 5 is a sectional view of a manufacturing process of a solar cell module according to a second embodiment of the present invention;

FIG. 6(a) is a sectional view of a solar cell module according to a second embodiment of the present invention;

FIG. 6(b) is a sectional view of a solar cell module according to a second embodiment of the present invention.

FIG. 7 is a sectional view of a solar cell module according to a second embodiment of the present invention;

FIG. 8 is shows a basic structure of a solar cell module; and

FIG. 9(a) is a plan view and sectional views showing a manufacturing process of a conventional solar cell module;

FIG. 9(b) is a plan view and sectional views showing a manufacturing process of a conventional solar cell module;

FIG. 9(c) is a plan view and sectional views showing a manufacturing process of a conventional solar cell module;

FIG. 9(d) is a plan view and sectional views showing a manufacturing process of a conventional solar cell module;

FIG. 9(e) is a plan view and sectional views showing a manufacturing process of a conventional solar cell module;

FIG. 9(f) is a plan view and sectional views showing a manufacturing process of a conventional solar cell module.

### DETAILED DESCRIPTION OF EXAMPLE EMBODIMENTS

### First Embodiment

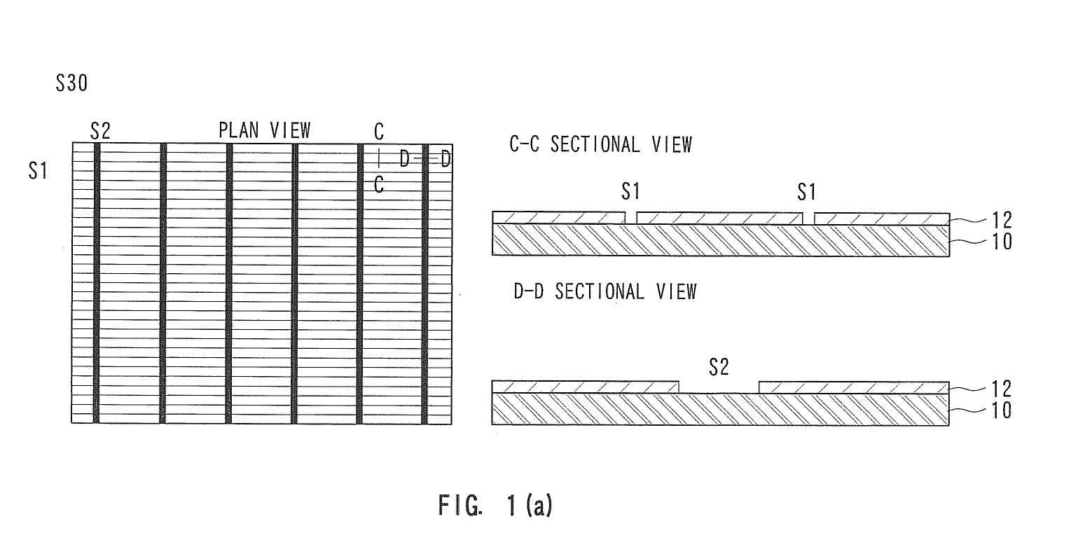

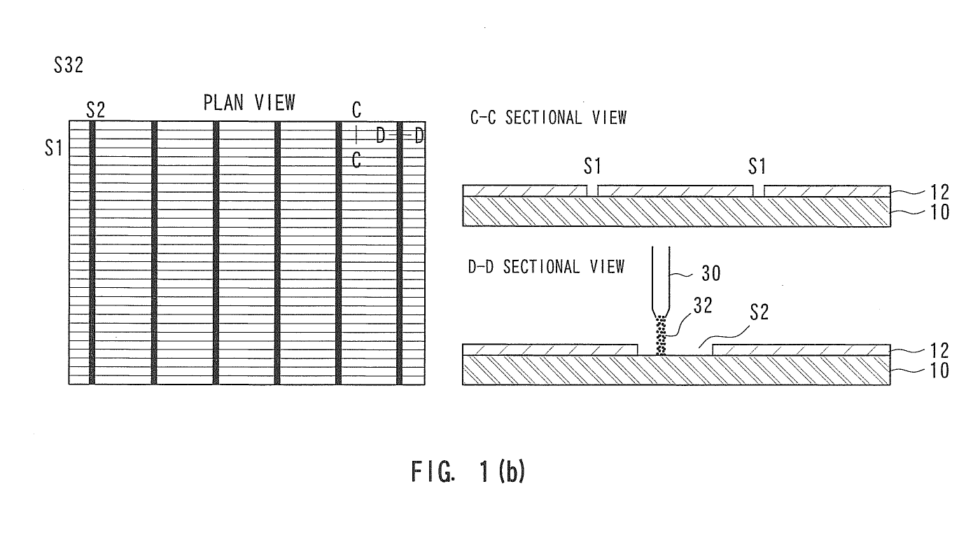

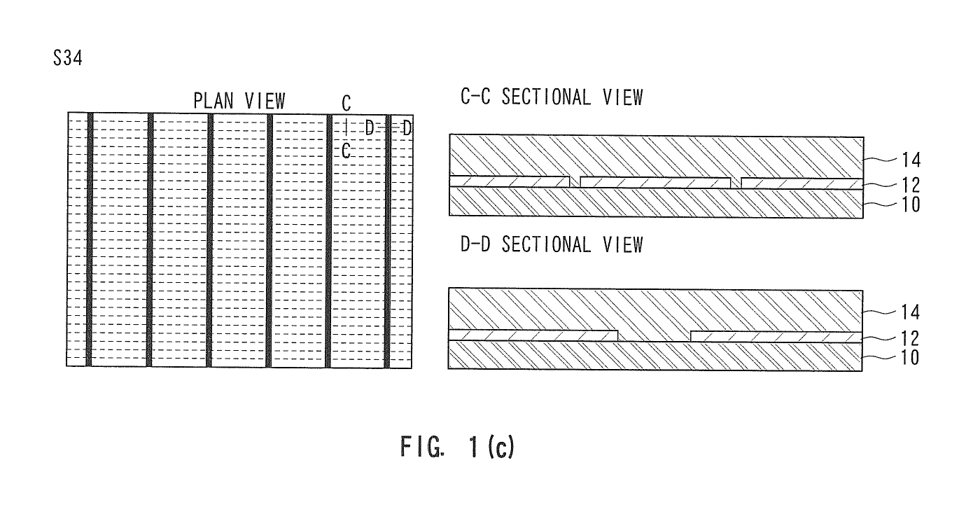

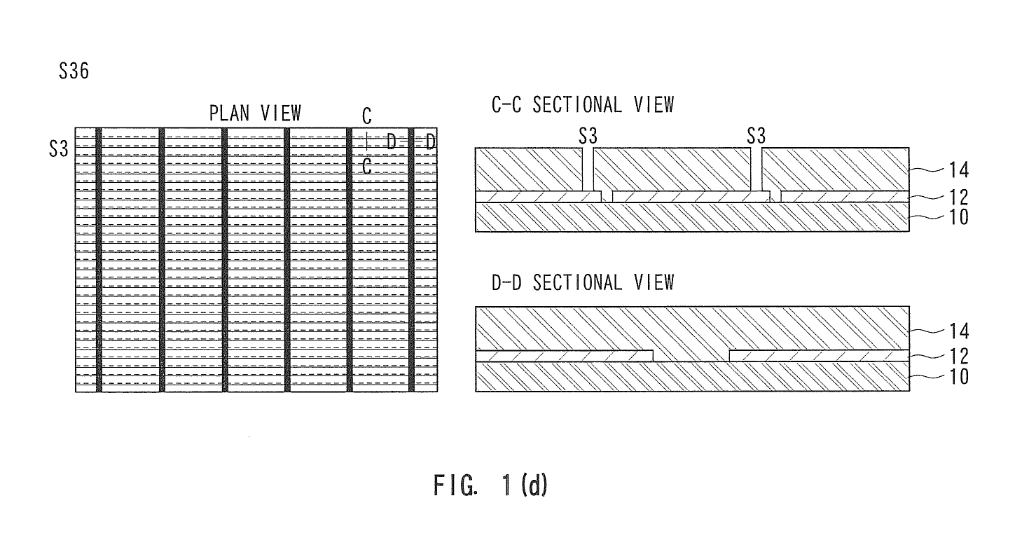

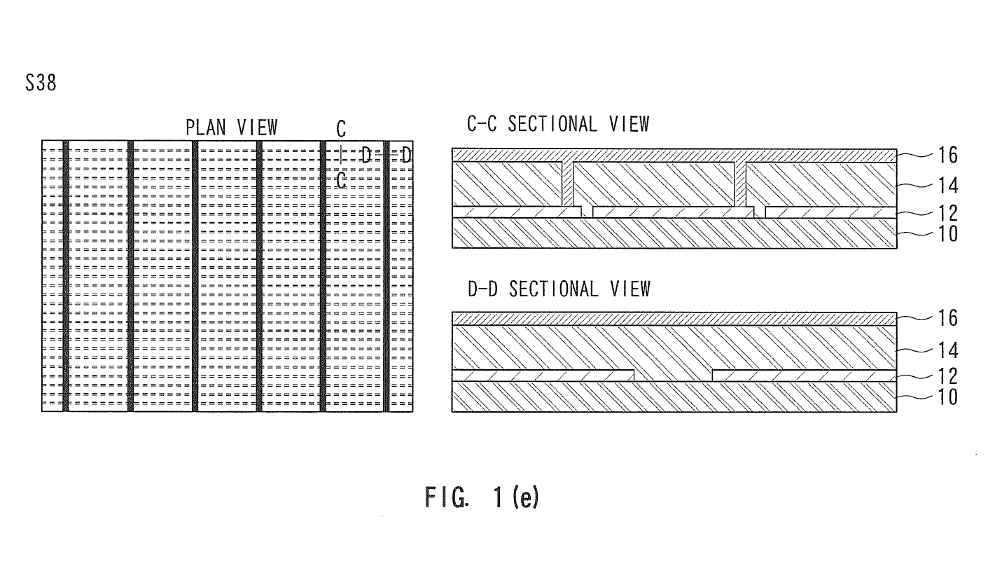

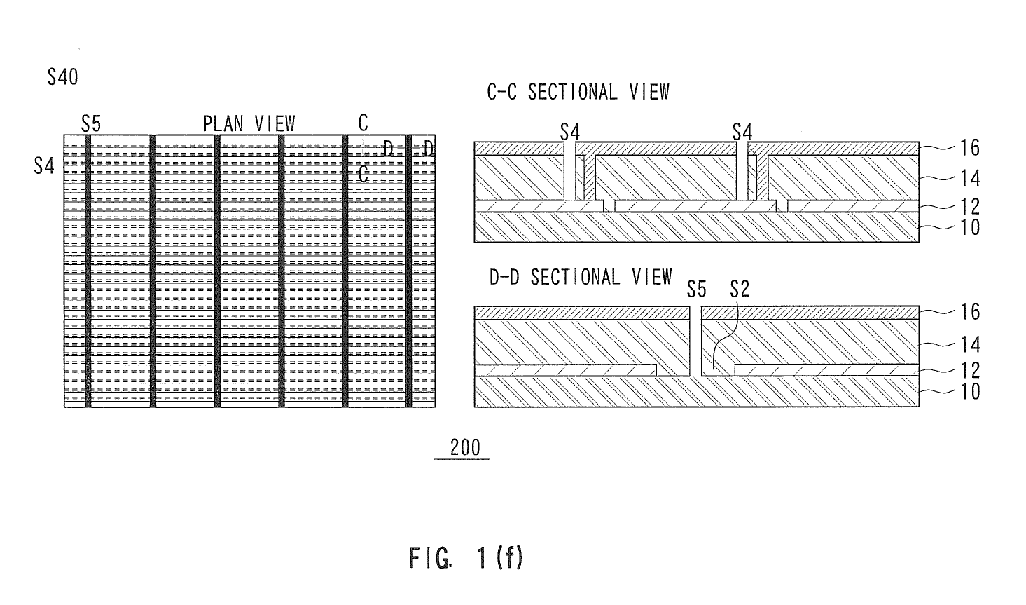

In FIGS. 1(a)-(f), a manufacturing process of a solar cell module 200 according to a first embodiment of the present invention is shown. FIGS. 1(a)-(f) are plan views and sectional views schematically showing each step of the manufacturing process of the solar cell module 200. The sectional views show sections cut along lines C-C and lines D-D of the plan views.

In step S30, as shown in FIG. 1(a), a slit S1 (shown horizontally in the figure) and a slit S2 (shown vertically in the figure) are formed by laser processing to divide a transparent electrode 12 formed on a transparent substrate 10. The transparent electrode 10 is made of any material capable of transmitting light beams having a wavelength used for photoelectric conversion in the solar cells, such as glass, plastic, or the like. The transparent electrode 12 may be made of a transparent conductive oxide (TCO) in which a material, such as tin(II) oxide (SnO₂), zinc oxide(ZnO), tin-doped indium oxide (ITO), is doped with tin(Sn), antimony(Sb), fluorine (F), aluminum (Al) or the like.

Preferably, a YAG laser having a wavelength of 1064 nm is used as a laser device for forming the slits S1 and S2. A laser beam is emitted from the direction of the transparent electrode 12, with the power of the laser being adjusted, to form the slits S1 and S2 by scanning in the direction of the slit S1 and the slit S2 perpendicular to the direction of the slit S1. It is noted that the laser for forming the slits S1 and S2 may be emitted from the direction of the transparent substrate 10.

Further, it is preferable to use a laser device having multiple ejection ports in which a plurality of laser beam emission ports are arranged at equal distances from each other in a direction perpendicular to the slit S1, since many slits S1 have to be formed to integrate multiple solar cells in series. For example, it is preferable to use a laser device having two to five laser beam emission ports. Accordingly, a large number of slits S1 can be formed at high speed to facilitate integration of many solar cells in series. It is noted that the slit S2 may have a larger size and lower processing accuracy than other slits, so that the processing conditions can be set easily even when the laser device having multiple emission ports is used.

In step S32, as shown in FIG. 1(b), the slit S2 is subjected to blasting. In blasting, particles 32 are sprayed from a nozzle 30 against the slit S2 where the transparent substrate 10 is exposed between the transparent electrode 12. Preferably, the particles 32 to be used are made of tungsten, alumina, silica, zirconium oxide, or the like. Also, the particles 32 to be used are preferably of diameter #1000 (number 1000) abrasive particles. For example, if tungsten particles are used as the particles 32, blasting is carried out by spraying abrasive particles of 68 g/min at a frequency of 80 Hz.

In blasting, a pressure to spray the particles 32 is from 0.1 MPa to 0.4 MPa, and more preferably from 0.15 MPa to 0.25 MPa. Table 1 below shows the blasting conditions. It is noted that a sample No. 7 represents the case where the blasting is conducted using a YAG laser having a wavelength of 1064 nm. Table 1 also shows the rating of peeling status of the transparent electrode 12 observed by human eyes using an optical microscope.

TABLE 1

| | | SUBSTRATE | | | | |
|---|---|---|---|---|---|---|
| | | TRANSPORT | SPRAYING | | | |
| SAMPLE | | SPEED | PRESSURE | SPRAYING | | PEELING |
| NO. | ABRASIVE | (m/min) | (MPa) | FLOW | | STATUS |
| 1 | WA #1000 | 1.0 | 0.15 | 80 | Hz (68 g) | GOOD |
| 2 | WA #1000 | 1.0 | 0.20 | 80 | Hz (68 g) | GOOD |
| 3 | WA #1000 | 1.0 | 0.25 | 80 | Hz (68 g) | GOOD |
| 4 | WA #1000 | 1.0 | 0.30 | 80 | Hz (68 g) | SLIGHTLY |
| | | | | | | PEELED |
| 5 | WA #1000 | 1.0 | 0.35 | 80 | Hz (68 g) | SLIGHTLY |
| | | | | | | PEELED |
| 6 | WA #1000 | 1.0 | 0.40 | 80 | Hz (68 g) | SLIGHTLY |
| | | | | | | PEELED |
| 7 | λ = 1064 nm | 500 mm/s | 14.6 W | 20 | kHz | PEELED |
| (LASER) | | | | | | |

In blasting, if the pressure to spray the particles 32 is extremely low, the protrusions and recesses 34 are hardly formed on the surface of the transparent substrate 10. On the other hand, if the pressure exceeds 0.30 Pa, it is observed that the transparent electrode 12 is peeled from the transparent substrate 10 due to blasting. Further, it is very likely that fine cracks are increased and may cause problems, such as cracks in the substrate.

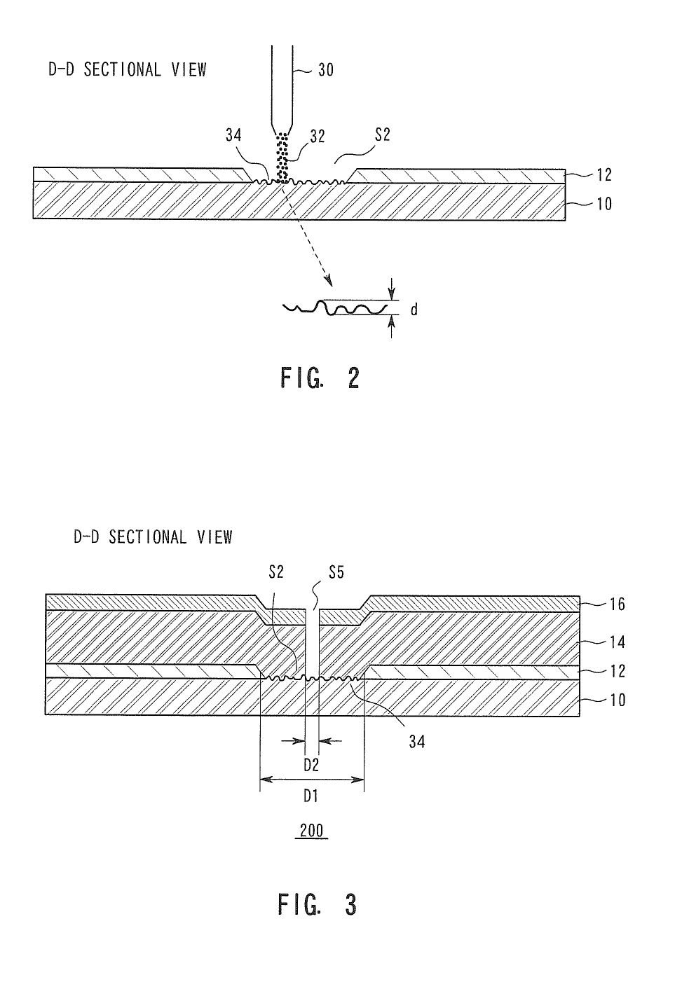

By blasting, as shown in an enlarged sectional view of FIG. 2, recesses and protrusions 34 are formed on the surface of the transparent substrate 10. Herein, an average difference in level between the top and bottom (a peak to valley value) of the recesses and protrusions 34 in the vertical cut of the transparent substrate 10 is preferably from 0.1 μm to 10 μm. More preferably, the value is from 1.0 μm to 3.0 μm.

It is to be noted that the difference in level d is measurable using a contact-type profilometer, a laser microscope, or a photo interference microscope. In the case of the contact-type profilometer, for example, an average difference in level d of, e.g., the slit S2, is an average value of the measurements scanned for about 1 mm with a stylus of the profilometer being in contact with the surface of the transparent substrate 10 exposed between the transparent electrode 12. It is also to be noted that the difference in level d may be measured after the blasting, or with the rear sheet of the finished solar cell module 200 peeled off.

If the difference in level d of the recesses and protrusions 34 is extremely small, it is less effective in increasing a contact area of the interface between the transparent substrate 10 and the photoelectric conversion unit 14, and thus diminishes the anti-peeling effect. On the contrary, if the difference in level d of the recesses and protrusions 34 is too large, fine cracks may be increased, which might cause the cracks and other defects in the substrate.

In step S34, as shown in FIG. 1(c), a photoelectric conversion unit 14 is formed to cover the transparent electrode 12 and the slits S1 and S2. The photoelectric conversion unit 14 is not particularly limited, but may be, for example, an amorphous silicon (a-Si) photoelectric conversion unit, a microcrystalline silicone (μc-Si) photoelectric conversion unit, or a tandem structure of such units. The photoelectric conversion unit 14 can be made from the plasma CVD or the like.

In step S36, as shown in FIG. 1(d), a slit S3 to divide the photoelectric conversion unit 14 is formed by laser processing. The slit S3 is formed in the direction of the slit S1 at a position in the vicinity of the slit S1 and not overlapping the slit S1, so that the slit S3 reaches the surface of the transparent electrode 12.

Preferably, a YAG laser having a wavelength of 532 nm (Second Harmonic Generation) is used as a laser device for forming the slit S3. A laser beam is emitted from the direction of the transparent electrode 10, with the power of the laser from the laser device being adjusted, to form the slit S3 by scanning in the direction parallel to the slit S1.

In step S38, as shown in FIG. 1(e), a rear surface electrode 16 is formed to cover the photoelectric conversion unit 14 and the slit S3. The rear surface electrode 16 is preferably made of a reflective metal. It is also preferable to provide a stacked structure of a reflective metal and a transparent conductive oxide (TCO). The reflective metal may be silver (Ag), aluminum (Al) or the like. The transparent conductive oxide (TCO) may be tin (II) oxide (SnO₂), zinc oxide (ZnO), indium tin oxide (ITO), or the like.

In step S40, as shown in FIG. 1(f), slits S4 and S5 are formed by laser processing to divide the photoelectric conversion unit 14 and the rear surface electrode 16. The slit S4 is formed to divide the photoelectric conversion unit 14 and the rear side electrode 16 in the direction of the slits S1 and S3 at a position in the vicinity of the slit S3 and not overlapping the slits S1 and S3, so that the slit S4 reaches the surface of the transparent electrode 12. Accordingly, the structure of a plurality solar cells connected in series in the direction of the slit S2 is provided. Further, a slit S5 is formed to divide the photoelectric conversion unit 14 and the rear surface electrode 16 in the region where slit S2 is formed, so that the slit S5 reaches the surface of the transparent electrode 12. A width D2 of the slit S5 is narrower than a width D1 of the slit S2. The slit S5 serves to electrically separate between adjacent solar cells arranged in the direction of the slit S1. Since the slit S5 is formed within the region where the slit S2 is formed, it is possible to emit the laser light from the direction of the transparent electrode 12 to form the slit S5 subsequent to forming the slit S4.

As such, the slits S1, S3, and S4 are provided to connect the adjacent solar cells in series, while the slit S2 and S5 are provided to arrange the serially connected solar cells in parallel. Accordingly, a structure is provided in which the adjacent solar cells arranged in the direction of the slit 1 are electrically separated from each other, and a plurality of serially connected solar cell groups, each group consisting of a plurality of solar cells, are arranged in parallel. Finally, the solar cells are connected in parallel to complete the solar cell module 200.

Preferably, a YAG laser having a wavelength of 532 nm (Second Harmonic Generation) is used as a laser device for forming the slits S4 and S5. A laser beam is emitted from the direction of the transparent electrode 10, with the power of the laser from the laser device being adjusted, to form the slit S4 by scanning in the direction parallel to the slits S1 and S3, which is followed by forming the slit S5 by scanning in the direction parallel to the slit S2.

It is to be noted that after the step S40, a step of removing the circumferential part of the solar cell module 200, for example, may be added. Also, after the step S40, a step of forming a back sheet or a resin layer to protect the surface of the solar cell module 200 may be added. The back sheet and/or the resin layer may serve as the protective layer of the solar cell module 200.

It is to be noted that in the first embodiment, the slit S2 is formed by laser processing followed by blasting the slit S2 to make the recesses and protrusions, but it is not limited thereto. For example, instead of forming the slit S2 by laser processing, blasting may be conducted against the transparent electrode 12, where the slit S2 is to be formed, to remove the transparent electrode 12, and simultaneously form the recesses and protrusions on the surface of the transparent substrate 10 underlying the transparent electrode 12. In addition, after the slit S2 is formed by laser processing, the recesses and protrusions may be formed on the surface of the transparent substrate 10 exposed through the slit S2 by wet etching using the remaining transparent electrode 12 as a mask. When the transparent substrate 10 is made of glass, hydrogen fluoride may be used in wet etching.

According to the first embodiment of the present invention, as shown in FIG. 3, because the recesses and protrusions 34 are provided on the surface of the transparent substrate 10 in the slit S2, the interface between the transparent substrate 10 and the photoelectric conversion unit 14 has an improved adhesion, so that the likelihood of peeling of the photoelectric conversion unit 14 from the transparent substrate 10 is minimized. In addition, when the protective layer is provided on the surface of the solar cell module 200, the interface between the protective layer and the transparent substrate 10 formed in the slit S5 has an improved adhesion, which also restricts the peeling of the protective layer from the transparent substrate 10. As a result, the solar cell module 200 has an improved anti-environmental characteristic to realize safe and steady power generation.

It is known that in the slits for dividing the transparent electrode 12, if the blasting is conducted selectively against the slit S2 which is wider than the slit S1, the peeling of the photoelectric conversion unit 14 from the transparent substrate 10 can be restricted effectively.

In addition, because the recesses and protrusions are formed on the surface of the transparent substrate 10 exposed in the slit S2, the peeling caused by the stress of irradiation of the laser light can be restricted during the formation of the slit S5. In particular, if the blasting is carried out at a pressure from 0.15 Pa to 0.25 Pa, a significant effect of restricting the peeling of the transparent electrode 12 from the transparent substrate 10 due to blasting can be obtained. As a result, the laser processing can be carried out steadily against the slit S5 within the region of the slit S2, and the manufacturing yield of the solar cell module 200 is improved.

On the other hand, by providing the recesses and protrusions on the surface of the transparent substrate 10 exposed in the slit S5, the light entering from the direction of the transparent substrate 10 is diffused by the recesses and protrusions and contributes to photoelectric conversion in the adjacent photoelectric conversion layer, rather than transmitting through the slit S5 as originally designed. As a result, the power generation efficiency of the solar cell module 200 is improved

### Second Embodiment

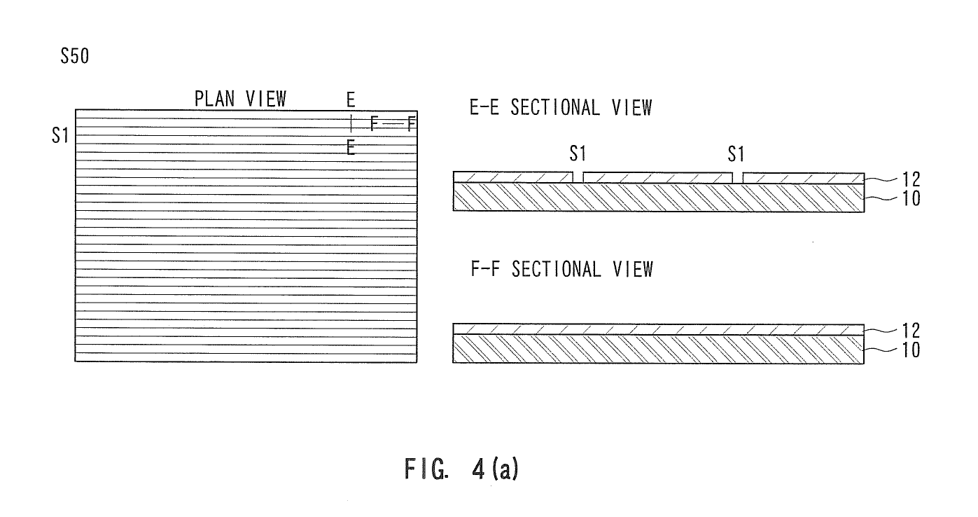

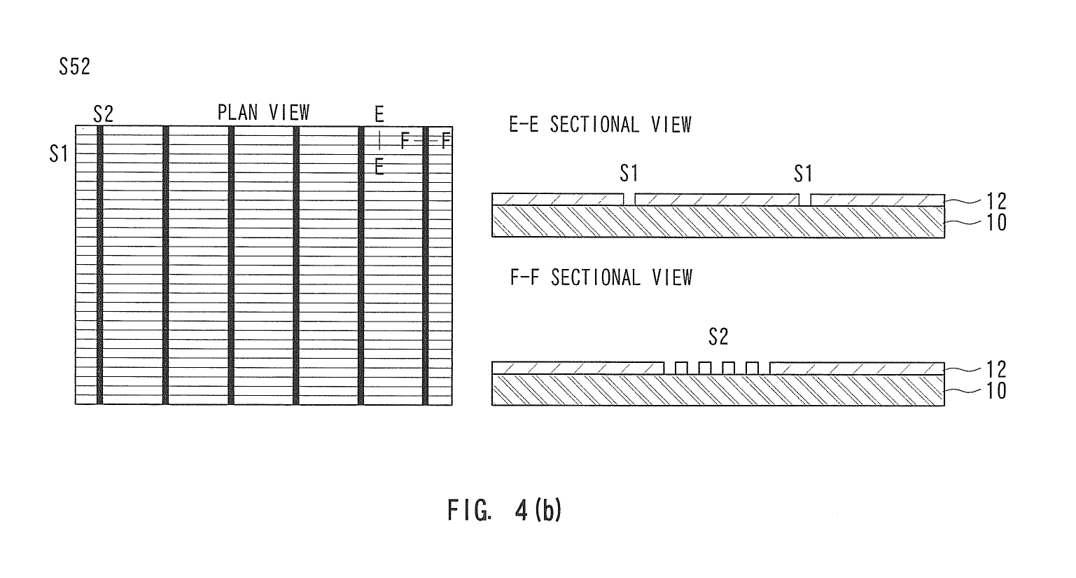

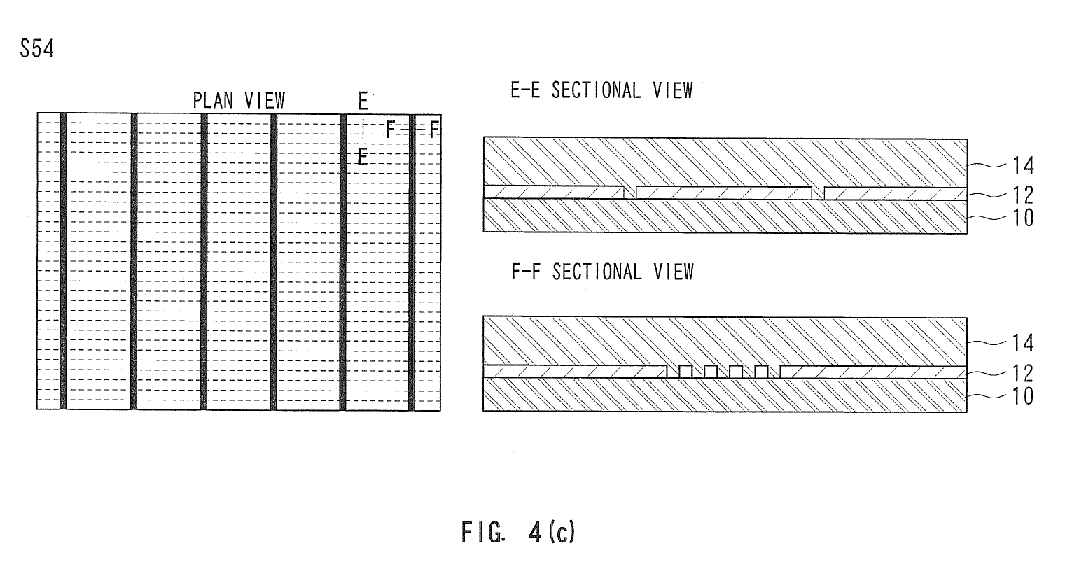

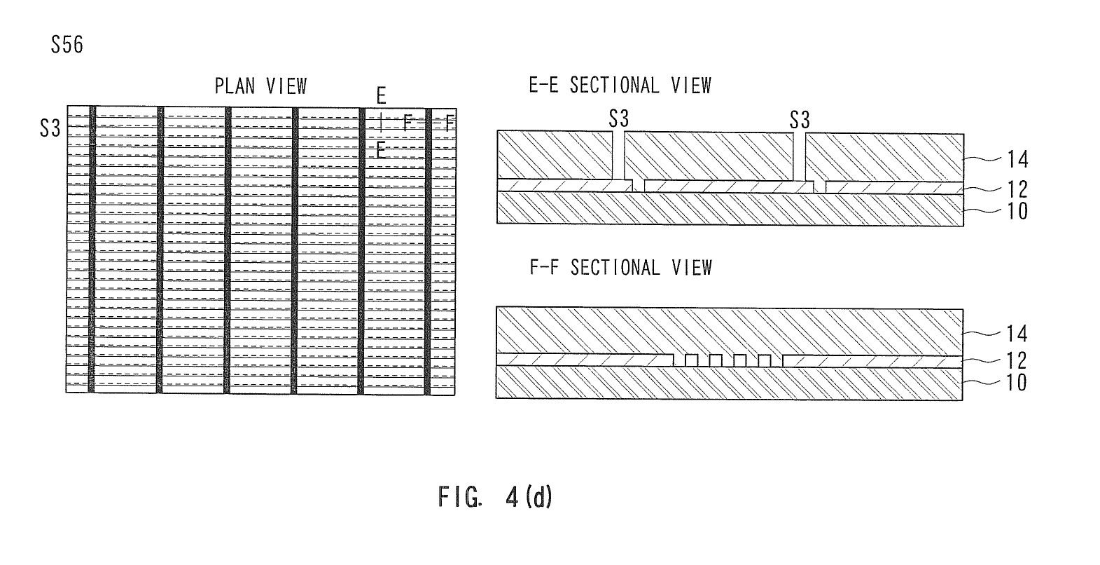

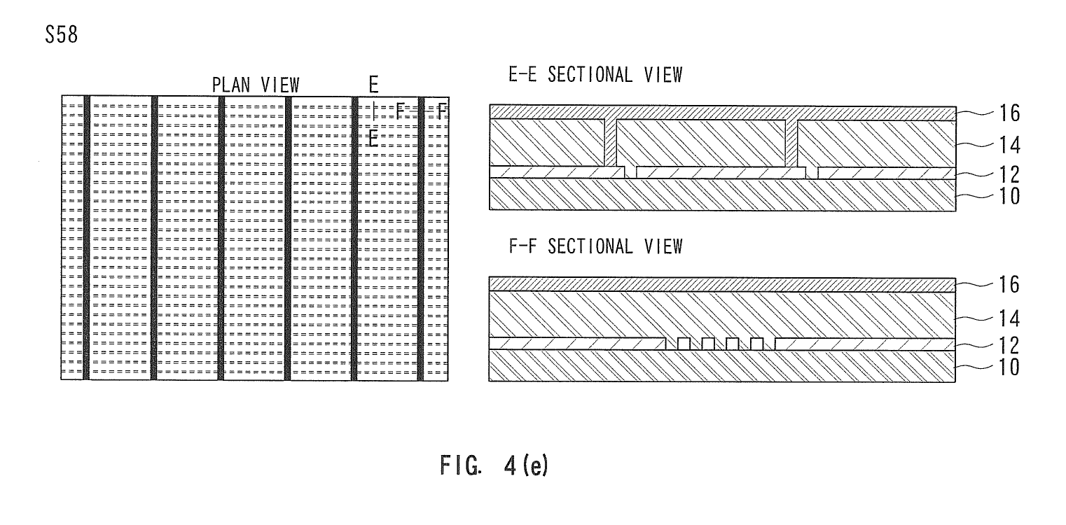

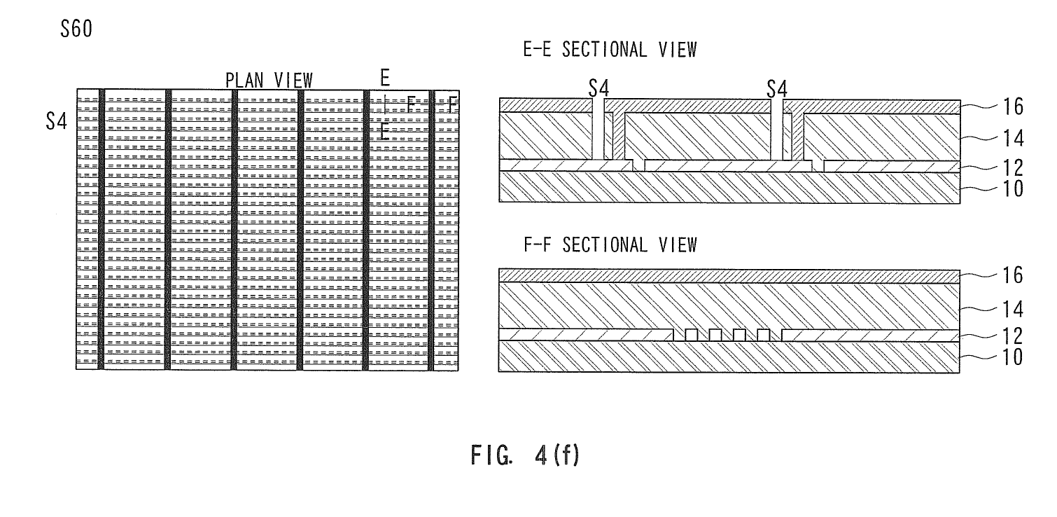

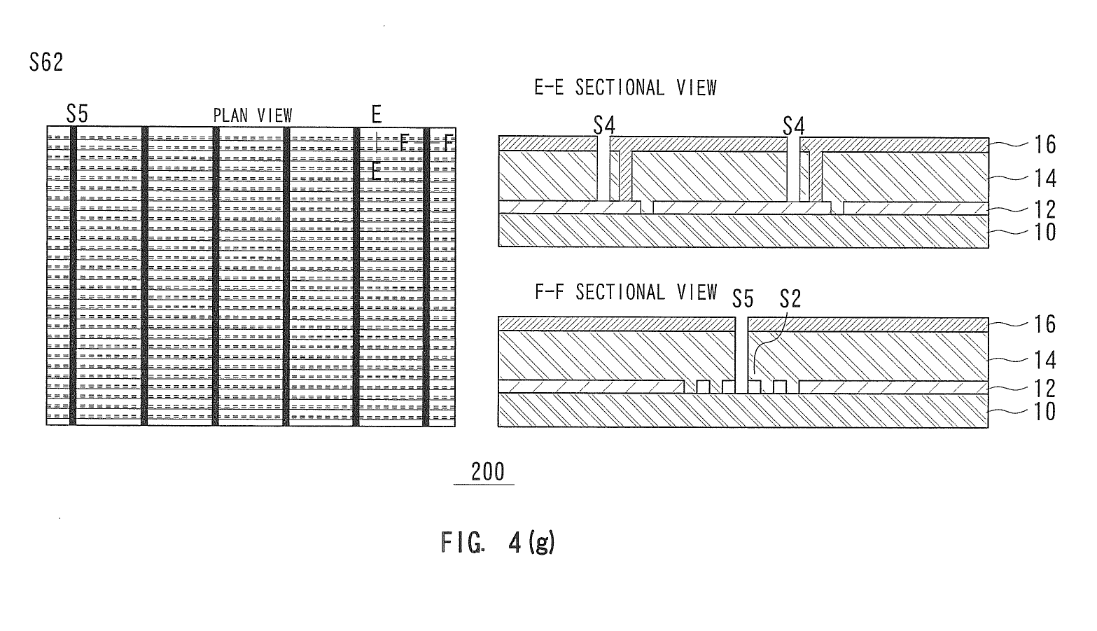

FIGS. 4(a)-(f) shows a manufacturing process of a solar cell module 300 according to a second embodiment of the present invention. FIGS. 4(a)-(f) are plan views and sectional views schematically showing each step of the manufacturing process of the solar cell module 300. The sectional views show sections cut along lines E-E and lines F-F of the plan views. In the following, it is to be noted that the description of the structure and the process steps similar to those of the first embodiment is not repeated.

In step S50, as shown in FIGS. 4(a), a slit S1 (shown horizontally) is formed to divide a transparent electrode 12 formed on a transparent substrate 10.

In step S52, as shown in FIG. 4(b), a slit S2 (shown vertically) is formed by laser processing to divide the transparent electrode 12 formed on the transparent substrate 10. The slit S2 is formed perpendicularly to the slit S1.

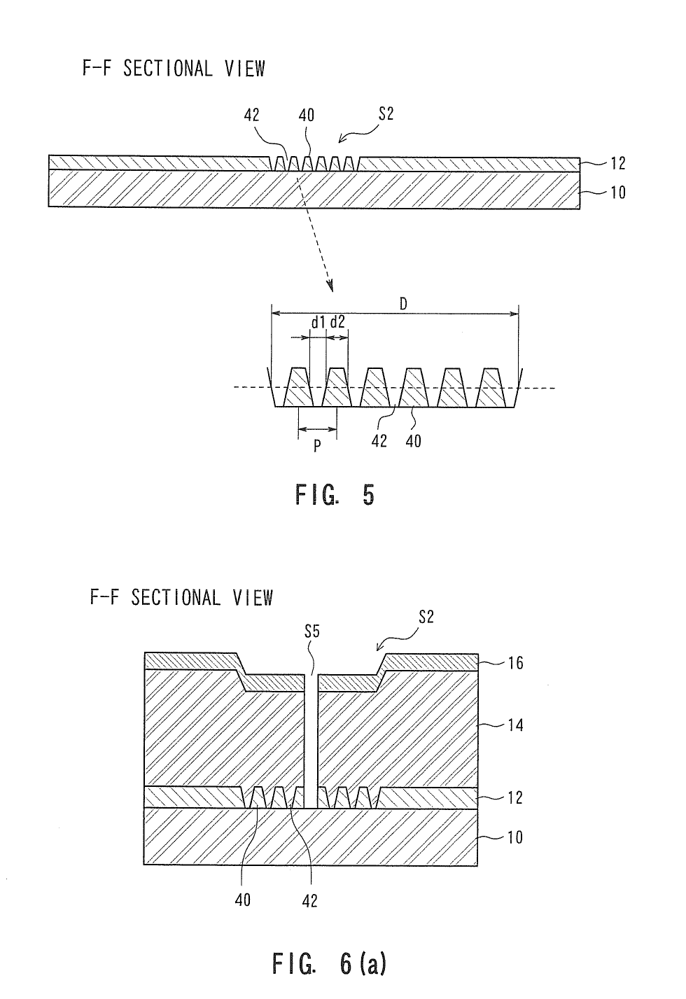

In the second embodiment of the present invention, as shown in an enlarged sectional view of FIG. 5, a laser light beam having a width of less than D/2 against a full width D of the slit S2 is used to form a plurality of slits 42 in such a manner that an island 40 of the transparent electrode 12 is left in the slit S2. In other words, the laser light beam having the width of less than D/2 is focused in a direction perpendicular to the slit S1, and scanned at a pitch P which is shorter than the full width D of the slit S2, to form the island 40 of the transparent electrode 12 which is separated by a slit 42 where the surface of the transparent substrate 10 is exposed. It is to be noted that, in this embodiment, the slit 42 is formed by using the laser light beam having a width approximately the same as the width of the slit S1.

It is assumed that a width d1 of the slit 42 is from 5 μm to 100 μm, and a width d2 of the island 40 is from 5 μm to 100 μm. Herein, the widths d1, d2, are average values of the slit 42 and the island 40, respectively, measured at a right angle of the extending direction of the island 40 in the middle of the thickness of a film of the transparent electrode 12. The widths d1 and d2 may be measured in a direction perpendicular to the extending direction of the island, using a contact-type profilometer or a laser optical interferometer. They are also determined by observing the section of the solar cell module 300 cut along the direction perpendicular to the extending direction of the island 40, using an optical microscope or an electronic microscope. In addition, the number of lines of the island 40 formed in the slit S2 is preferably from 4 to 100.

Preferably, a YAG laser having a wavelength of 1064 nm is used as a laser device for forming the slit S2. A laser beam is emitted from the direction of the transparent electrode 12, with the power of the laser from the laser device being adjusted, to form the slit S2. It is to be noted that the laser used to form the slit S2 may be emitted from the direction of the transparent substrate 10.

In steps S54-S58, as shown in FIGS. 4(c)-(e), similarly to the steps S34 to S38 of the first embodiment, the photoelectric conversion unit 14, the slit S3, and the rear surface electrode 16 are formed.

In step S60, as shown in FIG. 4(f), a slit S4 is formed by laser processing to divide the photoelectric conversion unit 14 and the rear surface electrode 16. The slit S4 is formed to divide the photoelectric conversion unit 14 and the rear side electrode 16 in the direction of the slits S1 and S3 at a position in the vicinity of the slit S3 and not overlapping the slits S1 and S3, so that the slit S4 reaches the surface of the transparent electrode 12. Accordingly, the structure of a plurality solar cells connected in series in the direction of the slit S2 is provided.

Preferably, a YAG laser having a wavelength of 532 nm (Second Harmonic Generation) is used as a laser device for forming the slit S4. A laser beam is emitted from the direction of the transparent electrode 10, with the power of the laser from the laser device being adjusted, to form the slit S4 by scanning in the direction parallel to the slits S1 and S3.

In step S62, as shown in FIG. 4(g), a slit S5 is formed by laser processing to divide the photoelectric conversion unit 14 and the rear surface electrode 16. The slit S5 is formed to reach the surface of the transparent electrode 12 in the region where the slit S2 is formed to divide the photoelectric conversion unit 14 and the rear side electrode 16 formed in the slit S2. The slit S5 electrically separates the adjacent solar cells in the direction of the slit S1.

A YAG laser having a wavelength of 1064 nm is used as a laser device for forming the slit S5. A laser beam is emitted from the direction of the rear side electrode 16, with the power of the laser from the laser device being adjusted, to form the slit S5 by scanning in the direction parallel to the slit S2.

Also, a YAG laser having a wavelength of 532 nm (Second Harmonic Generation) is used with the power of the laser from the laser device being adjusted to form the slit S5 by scanning in the direction parallel to the slit S2.

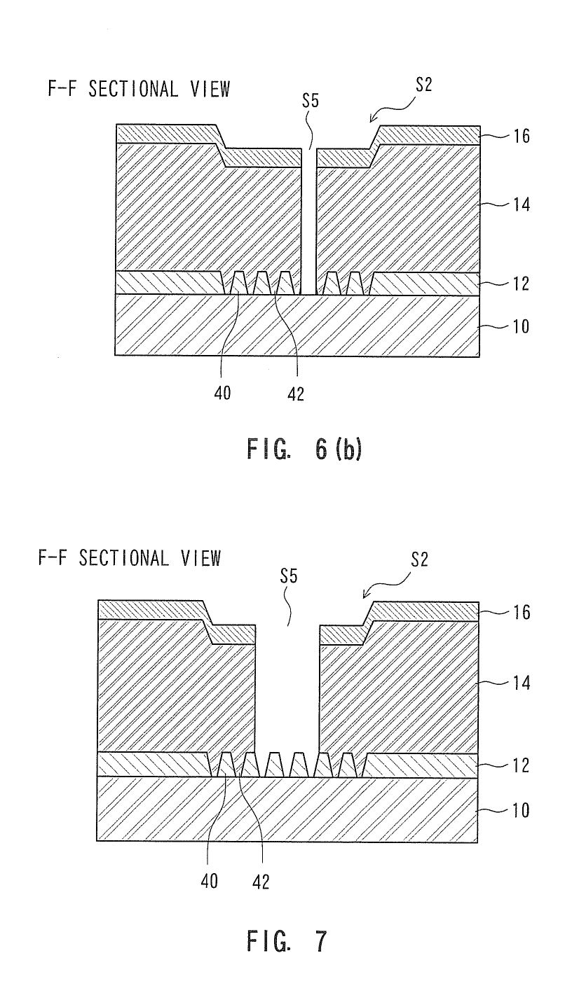

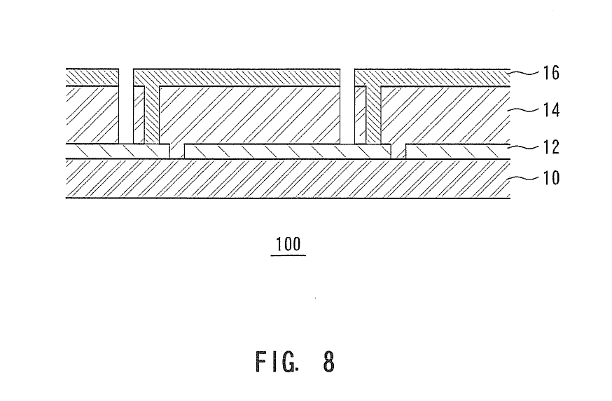

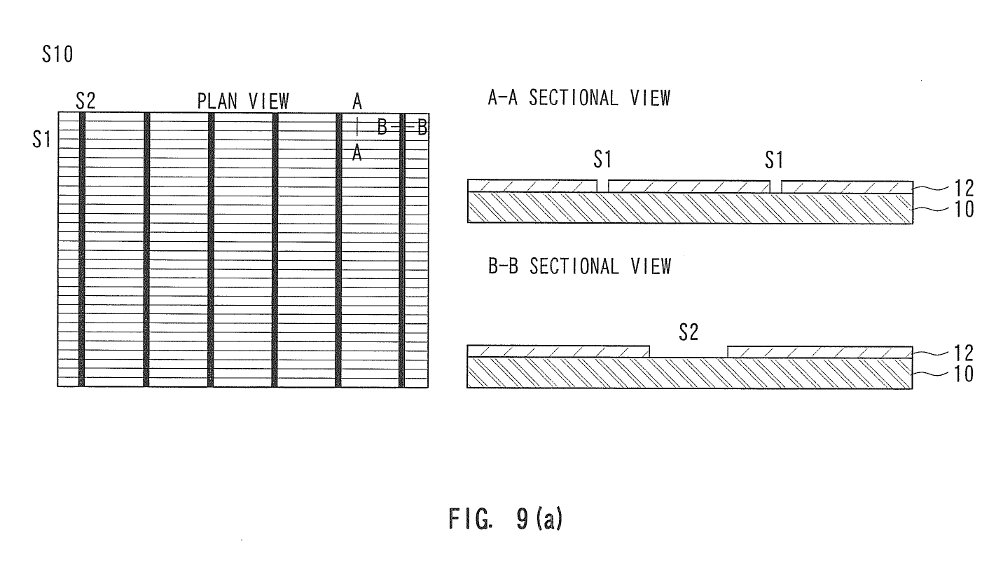

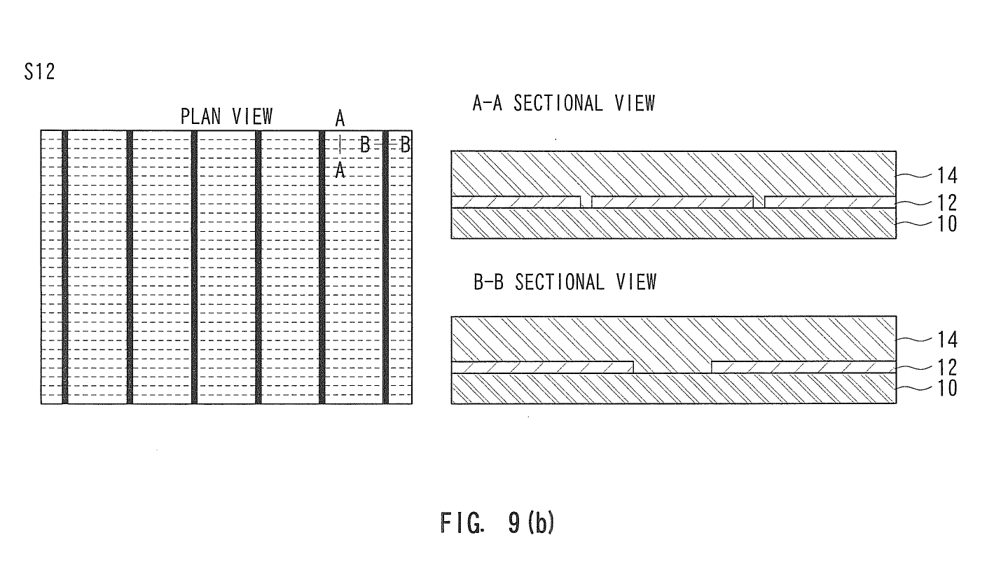

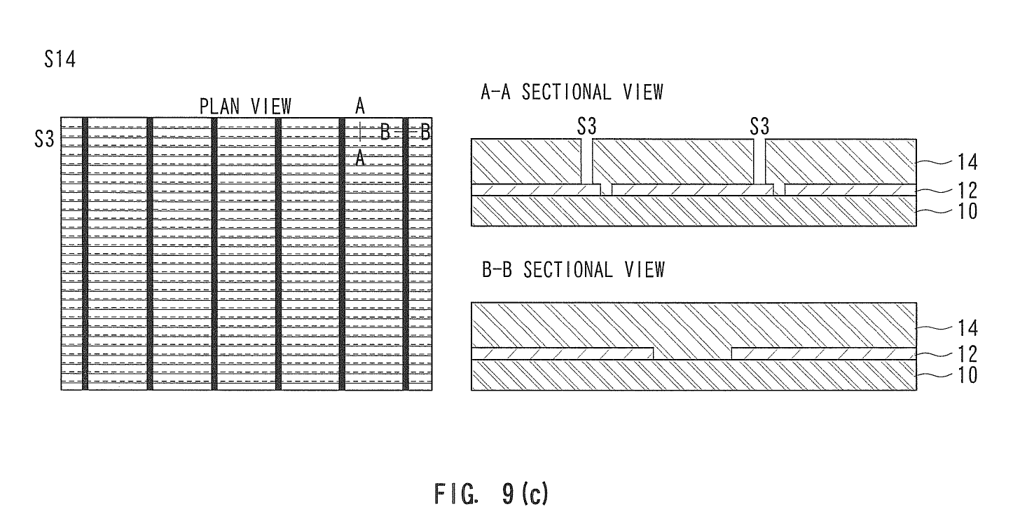

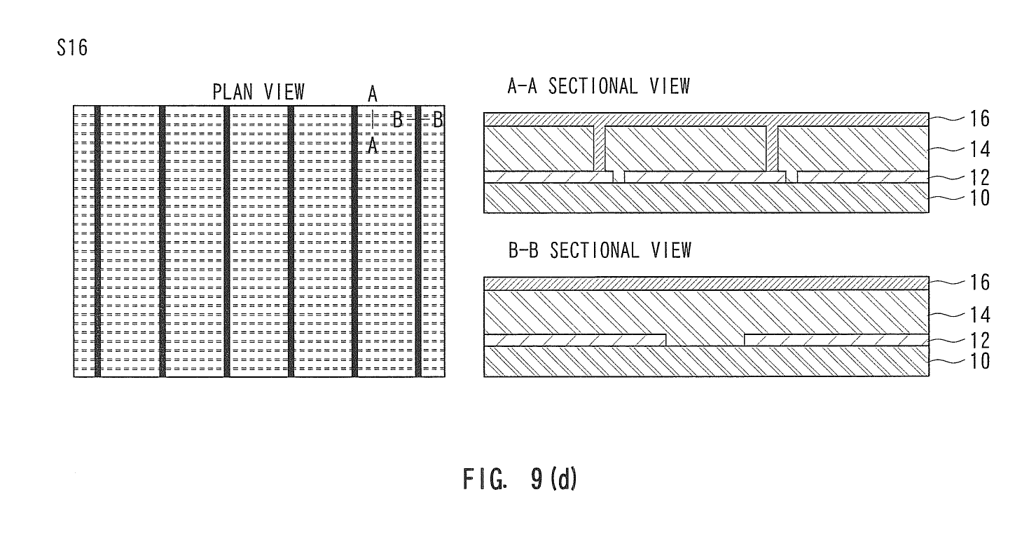

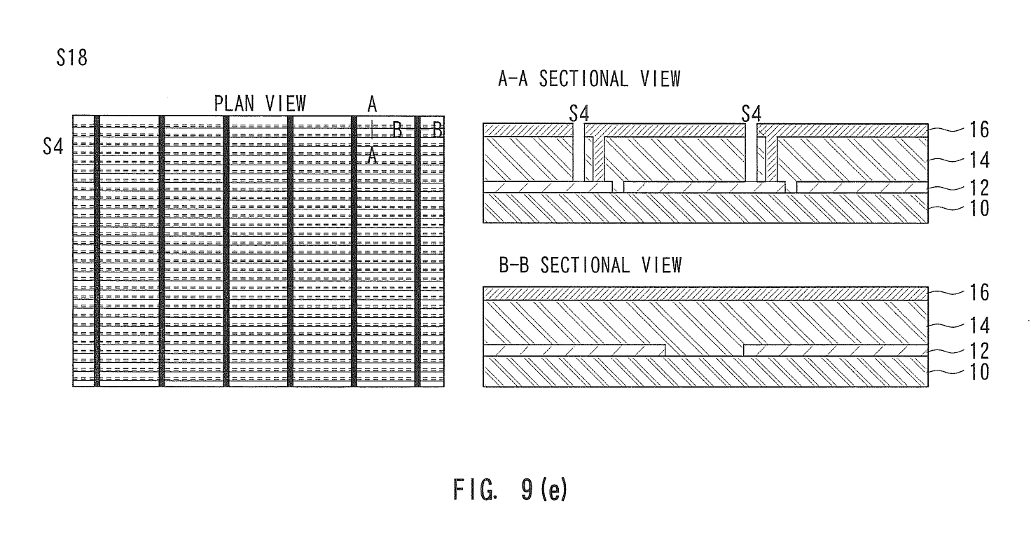

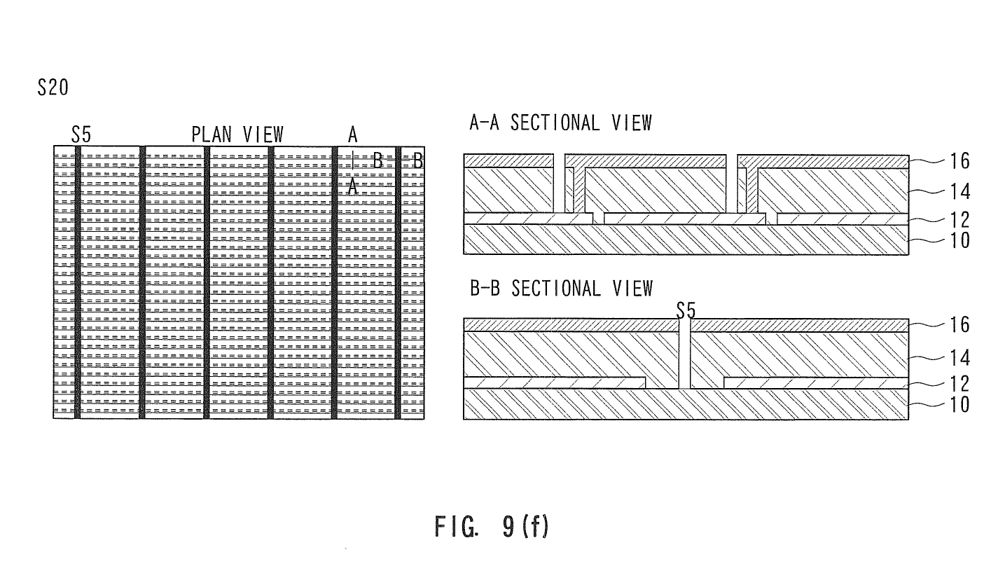

It is noted that the slit S5 may be formed by focusing the laser light on a position of the slit 42 formed in the slit S2, or otherwise formed, as shown in FIG. 6(b), by irradiating the laser light on a part of the island 40 of the transparent electrode 12 left in the slit S2, followed by removing the transparent electrode 12.

As described above, the slits S1, S3 and S4 are provided to connect adjacent solar cell groups in series, while the slits S2 and S5 are provided to arrange the serially connected solar cells in parallel. Accordingly, a structure is provided in which the adjacent solar cells arranged in the direction of the slit 1 are electrically separated from each other, and a plurality of serially connected solar cell groups, each group consisting of a plurality of solar cells, are arranged in parallel. Finally, the solar cells are connected in parallel to complete the solar cell module 300.

It is noted that, after the step S60, a step of, for example, removing the circumferential part of the solar cell module 300 may be added. Also, after the step S60, a step of forming a back sheet or a resin layer to protect the surface of the solar cell module 300 may be added. The back sheet and/or the resin layer may serve as the protective layer of the solar cell module 300.

According to the second embodiment of the present invention, as shown in FIGS. 6(a) and (b), because the island 40 of the transparent electrode 12 is left in the slit S2, an area where the transparent substrate 10 and the photoelectric conversion unit 14, both having a low adhesion, are in direct contact with each other is minimized in the slit S2. As a result, the adhesion of the interface between the transparent electrode 10 and the photoelectric conversion unit 14 is improved, and the peeling of the photoelectric conversion unit 14 from the transparent substrate 10 is restricted.

In addition, because a plurality of slits 42 where the transparent substrate 10 and the photoelectric conversion unit 14 are in direct contact with each other are provided in the slit S2, even if the insulation resistance is decreased in a particular slit 42, it is still possible to maintain sufficient insulation between adjacent transparent electrodes 12 of the photoelectric conversion unit 14 across the slit S2 by other slits 42.

Further, because the slit S2 consists of a plurality of slits 42 and islands 40, the peeling caused by the stress of laser irradiation can be restricted. As a result, the laser processing of the slit S5 can be carried out steadily in the slit S2, and the manufacturing yield of the solar cell module 300 can be improved.

In particular, when the photoelectric conversion unit made of microcrystalline silicon (μc-Si) is used, the peeling of the transparent substrate 10 easily happens due to a high film pressure of the microcrystalline silicon layer of the microcrystalline silicon photoelectric conversion unit, so that the effect of restriction of peeling of the above structure is apparent and easily perceived.

For example, as shown in FIG. 7, if the width of the slit is larger than the width of the slit 42 so that the slit S5 spans a plurality of islands 40 and slits 42, there is provided an improved adhesion between the protective layer and the underlying layer (the island 40 and the transparent substrate 10) due to the islands 40 and the slits 42 formed in the slit S5, so that the peeling of the protective layer from the underlying layer is restricted. Thus, the environmental durability of the solar cell module 300 can be improved and the stable power generation is realized.

Further, because the slit S2 is formed by a plurality of slits 42 and islands 40, even if the residue is left in the slits 42 due to the photoelectric conversion unit 14 or the rear surface electrode 16 during the subsequent irradiation of the laser light for forming the slit S5, it is still possible to maintain sufficient insulation between the adjacent transparent electrodes 12 of the photoelectric conversion unit 14 across the slit S2 by other slits 42 arranged in the region outside the slit S5.

### PARTS LIST

10: TRANSPARENT SUBSTRATE
12: TRANSPARENT ELECTRODE
14: PHOTOELECTRIC CONVERSION UNIT
16: REAR SURFACE ELECTRODE
30: NOZZLE
32: PARTICLES
34: RECESSES AND PROTRUSIONS
40: ISLAND OF TRANSPARENT ELECTRODE
42: SLIT
100, 200, 300: SOLAR CELL MODULE

What is claimed is:

1. A solar cell module consisting of a plurality of photoelectric conversion elements connected in series, each of which having a first electrode, an electricity generating layer, and a second electrode sequentially stacked on a substrate, the solar cell module comprising:
a dividing slit having:
a region where the first electrode is removed to a first width; and
a region which overlaps the region where the first electrode is removed, and which has the electricity generating layer and the second electrode removed therefrom to a second width narrower than the first width;
wherein recesses and protrusions are provided on the surface of the substrate in the dividing slit.

2. A solar cell module according to claim 1, wherein an average difference in level of the recesses and protrusions is from 0.1 μm to 10 μm.

3. A method of manufacturing a solar cell module consisting of a plurality of photoelectric conversion elements connected in series, each of which having a first electrode, an electricity generating layer, and a second electrode sequentially stacked on a substrate, comprising:
a first step of forming the first electrode on the substrate;
a second step of removing a part of the first electrode to a first width and forming recesses and protrusions on the surface of the substrate by blasting a region where the first electrode is removed; and
a third step sequentially stacking the electricity generating layer and the second electrode on the substrate; and
a fourth step of removing the electricity generating layer and the second electrode to a second width narrower than the first width in a region which overlaps the region where the first electrode is removed.

4. A method of manufacturing a solar cell module according to claim 3, wherein the second step removing a part of the first electrode by blasting.

5. A solar cell module consisting of a plurality of photoelectric conversion elements connected in series, each of which having a first electrode, an electricity generating layer, and a second electrode sequentially stacked on a substrate, the solar cell module comprising:
a first slit having an island of the first electrode arranged in the direction of the serial connection of the photoelectric conversion elements and sandwiched by a plurality of slits from which the first electrode is removed to leave the island; and
a second slit formed within the region where the first slit is provided, and having the first electrode, the electricity generating layer, and the second electrode removed therefrom to reach the substrate;

6. A solar cell module according to claim 5, further comprising a protective layer stacked on the substrate including the second electrode, wherein
the width of the second slit is wider than the width of the slit.

7. A method of manufacturing a solar cell module consisting of a plurality of photoelectric conversion elements connected in series, each of which having a first electrode, an electricity generating layer, and a second electrode sequentially stacked on a substrate, comprising:
a first step of forming the first electrode on the substrate;
a second step of forming a first slit having an island of the first electrode arranged in the direction of the serial connection of the photoelectric conversion elements and sandwiched by a plurality of slits from which the first electrode is removed to leave the island;
a third step of sequentially stacking the electricity generating layer and the second electrode on the first electrode including at least part of the island; and
a fourth step of forming a second slit by removing the first electrode, the electricity generating layer, and the second electrode in the region where the first slit is formed, so that the second slit reaches the substrate.
